(19) United States
(12) Patent Application Publication
(10) Pub. No.: US 2008/0006887 A1
(43) Pub. Date: Jan. 10, 2008

(54) Semiconductor Devices Including Impurity Doped Region and Methods of Forming the Same

(76) Inventors: Tetsuji Ueno, Yeongtong-gu (KR); Hwa-Sung Rhee, Seongnam-si (KR); Ho Lee, Cheonan-si (KR)

Correspondence Address: F. CHAU & ASSOCIATES, LLC, 130 WOODBURY ROAD, WOODBURY, NY, 11797, US

(21) Appl. No.: 11/668,891

(22) Filed: Jan. 30, 2007

(30) Foreign Application Priority Data
Feb. 1, 2006 (KR) 10-2006-0009775

(51) Int. Cl. H01L 29/78; H01L 21/265; H01L 21/336

(52) U.S. Cl. 257/408; 438/303; 438/530; 257/E29.266; 257/E21.437; 257/E21.334

(57) ABSTRACT

A semiconductor device including an impurity doped region and a method of forming the same. The method includes implanting cluster-shaped dopant ions into a semiconductor substrate to form an impurity implantation region. An annealing process is performed on the impurity implantation region to form an impurity doped region.

### CROSS-REFERENCE TO RELATED APPLICATIONS

This application claims priority under 35 U.S.C § 119 to Korean Patent Application No. 10-2006-0009775, filed on Feb. 1, 2006, the entire contents of which are hereby incorporated by reference.

### BACKGROUND OF THE INVENTION

1. Technical Field

The present disclosure relates to semiconductor devices and methods of forming the same, and more particularly, to semiconductor devices including an impurity doped region and methods of forming the same.

2. Discussion of the Related Art

Semiconductor devices may include a semiconductor substrate having regions that are doped with impurities. Impurities may be either p-type dopants or n-type dopants. The impurity doped regions may conduct electricity in a desired manner. Impurity doped regions are generally used as source/drain regions of a MOS (metal oxide semiconductor) field effect transistor (hereinafter, referred to as a transistor). Generally an impurity doped region is formed by implanting dopants into the semiconductor substrate using an ion implantation method. The implanted dopants may then be activated through an annealing process.

As semiconductor devices become more highly integrated, junction depth of source/drain regions of transistors must be reduced. In particular, junction depths of lightly doped regions must he reduced. Examples of lightly doped regions include source/drain regions of a lightly doped drain (LDD) structure and/or extended portions of extended source/drain regions. By reducing junction depths, degradation of leakage current between a source and a drain due to such factors as punch-through may be minimized.

A conventional method of forming a junction of an impurity doped region having a small depth will now be described with reference to FIG. 1. Impurity doped region may be used as a lightly doped region and/or as an extended portion of extended doped regions. FIG. 1 illustrates a concentration of dopants as a function of a depth of a conventional impurity doped region. In FIG. 1 a horizontal axis represents a depth of a semiconductor substrate and a vertical axis represents a corresponding concentration of dopants.

Referring to FIG. 1, dopants are implanted into a semiconductor substrate using an ion implantation method to form an impurity implantation region. According to a well-known ion implantation method, monoatomic or monomolecular dopant ions are electrically accelerated and implanted. The dopants implanted using the well-known ion implantation method are implanted in such a way that the implantation range has a Gaussian distribution with a width greater than an average projected range (Rp). In the conventional method of forming source/drain regions having a small junction depth, dopant ions are implanted into the Rp near a surface of the semiconductor substrate with low energy. As a result, the impurity implantation region has an implant concentration profile 10 as illustrated in FIG. 1. According to the implant concentration profile 10, the peak concentration is represented at a surface of the semiconductor substrate, and the concentration of the implanted dopants sharply decreases as the depth from the surface of the semiconductor substrate increases.

After forming the impurity implantation region, the implanted dopants are activated through an annealing process to form an impurity doped region in the semiconductor substrate. A doping concentration profile 20 of the impurity doped region is seen in FIG. 1. A rapid thermal annealing (RTA) process may be used for obtaining a small junction depth of the impurity doped region in a short period of time. The RTA process may minimize diffusion of the implanted dopants to obtain the impurity doped region having a small junction depth. As shown by the implant and doping concentration profiles 10 and 20, the dopants around a surface of the semiconductor substrate at a high concentration are diffused downward through the RTA process.

According to the conventional method, the implanted dopants diffuse through the RTA process. The RTA process includes an annealing step of increasing a temperature and a step of decreasing a temperature, etc. Therefore, the semiconductor substrate may be exposed to a high temperature for a period of time from several seconds to several minutes during the RTA process. As semiconductor devices become more highly integrated, semiconductor critical dimensions are reduced to a nanometer-scale. Accordingly, the junction depth of the impurity doped region may increase and the semiconductor device may degrade despite the RTA process. Furthermore, when an annealing, temperature of the RTA process is increased, the step of increasing a temperature and/or the step of decreasing a temperature in the RTA process are lengthened. Therefore the semiconductor substrate's exposure to a high temperature may increase as the junction depth of the impurity doped region is increased. The above-described described factors may limit the extent to which the annealing temperature of the RTA process may be increased.

Dopants are implanted into a surface of the semiconductor substrate. Therefore, the peak concentration of dopants may be found at the surface of the semiconductor and the concentration of the implanted dopants sharply decreases as depth increases. Accordingly, a specific resistance of the impurity doped region may be decreased by forming an excessive peak concentration at the surface of the semiconductor substrate. Due to the excessive peak concentration and the limited annealing temperature of the RTA process, a great amount of inactivated dopant may exist around an upper surface of the impurity doped region, which is the surface of the semiconductor substrate. The amount of dopants implanted into the surface of the semiconductor substrate may therefore exceed a solubility limit concentration 30. Accordingly, levels of inactivated dopants may greatly exceed levels of activated dopants at the surface of the semiconductor substrate. In FIG. 1, a region 40 represents an amount of the inactivated dopants in the impurity doped region. As can be seen by the implant concentration profile 10, it may be necessary to implant a great amount of dopant into the surface of the semiconductor substrate such that an upper portion of the impurity doped region can have a low resistance necessary for electrical operation. Therefore, the level of inactivated dopants may be more than 10 times the level of activated dopants at the surface of the semiconductor substrate. This excess of inactivated dopant may lead to detects such as vacancy and/or dislocation in a surface of the impurity doped region. As a result, an electrical resistance of the impurity doped region may be increased and the semiconductor device may be degraded.

In addition, channeling may occur when the dopant ions are implanted. Therefore, as illustrated in FIG. 1, a deep channeling tail may be created in the implant concentration profile 10 represented by the dotted line. As a result, the junction depth of the impurity doped region may be further increased.

### SUMMARY OF THE INVENTION

Exemplary, embodiments of the present invention provide a highly integrated semiconductor device and a method of forming the same.

Exemplary embodiments of the present invention also provide a semiconductor device including an impurity doped region having an excellent electrical property and a small junction depth and a method of forming the same.

Exemplary embodiments of the present invention provide methods of forming a semiconductor device including an impurity doped region, the methods include implanting cluster-shaped dopant ions into a semiconductor substrate to form an impurity implantation region and performing an annealing process on the impurity implantation region to form an impurity doped region. The cluster-shaped dopant ions have a plurality of dopant atoms or a plurality of dopant molecules that are bound with one another.

In some exemplary embodiments, an upper portion of the impurity implantation region may include a maximum implantation portion having the highest dopant concentration. In this case, a dopant concentration of the maximum implantation portion may be 4 times smaller than a solubility limit concentration according to an annealing temperature of a laser annealing process. In addition, the dopant concentration of the maximum implantation portion may be equal to or higher than the solubility limit concentration. The dopant concentration of the maximum implantation portion may range from 5×10¹⁹/cm³ to 2×10²²/cm³. When the dopant is boron, the dopant concentration of the maximum implantation portion may range from 5×10¹⁹/cm³ to 2.4×10²¹/cm³. An annealing temperature of the laser annealing process may be within the range of about 1000-1450° C. The laser annealing process may be performed by irradiating a laser beam to the impurity implantation region. The annealing time of the laser annealing process may range from about 1 microsecond to about 1 second. An upper doped portion, which is the upper portion of the impurity doped region, may have a concentration dispersion less than 20%. A lower surface of the impurity doped region may be formed at a first depth from an upper surface of the semiconductor substrate and a lower surface of the upper doped portion may be formed at a second depth from the upper surface of the semiconductor substrate. Here, the second depth may be equal to or larger than ¼ of the first depth and may be smaller than the first depth. A lower doped portion, which is a lower portion of the impurity doped region, may be formed at the first depth. A dopant concentration of the lower doped portion may sharply decrease as depth increases. A depth of a lower surface of the impurity doped region may be about 1-15 nm. The method may further include forming a gate electrode disposed on the semiconductor substrate with a gate insulating layer interposed therebetween before the forming of the impurity implantation region. The cluster-shaped dopant ions are implanted using the gate electrode as a mask and the impurity implantation regions are formed at both sides of the gate electrode in the semiconductor substrate.

Exemplary embodiments of the present invention provide semiconductor devices including an impurity doped region. The semiconductor devices include a semiconductor substrate and an impurity doped region formed in the semiconductor substrate. An upper doped portion, which is an upper portion of the impurity doped region, has a dopant concentration dispersion of less than 20%, a dopant concentration of a lower doped portion, which is a lower portion of the impurity doped region, sharply decreases as depth increases.

In exemplary embodiments, a lower surface of the impurity doped region may be located at a first depth from an upper surface of the semiconductor substrate and a lower surface of the upper doped portion may be formed at a second depth from the upper surface of the semiconductor substrate. Here, the second depth may be equal to or larger than ¼ of the first depth and smaller than the first depth and a lower surface of the lower doped portion may be located at the first depth. An amount of inactivated dopant may be smaller than 3 times an amount of activated dopant in the upper doped portion. The activated dopant may exist in the upper doped portion and inactivated dopand may be absent from the upper doped portion. A maximum dopant concentration of the upper doped portion may be higher than about 4×10¹⁹/cm³ and lower than about 2×10²²/cm³. When the dopant is boron, the maximum dopant concentration of the upper doped portion may be higher than about 4×10¹⁹/cm ³ and lower than about 2×10²¹/cm³. A depth of the impurity doped region may be about 1-5 nm. The semiconductor device may further include a gate electrode disposed at a side of the impurity doped region on the semiconductor substrate and a gate insulating layer interposed between the gate electrode and the semiconductor substrate.

### BRIEF DESCRIPTION OF THE DRAWINGS

The accompanying figures are included to provide a further understanding of the present disclosure and are incorporated in and constitute a part of this specification. The drawings illustrate exemplary embodiments of the present invention and, together with the description, serve to explain principles of the present disclosure. In the figures:

FIG. 1 is a graph illustrating the concentration of dopants as a function of the depth of a conventional impurity doped region;

FIGS. 2 and 3 are sectional views illustrating a method of forming a semiconductor device including an impurity doped region according to an exemplary embodiment of the present invention;

FIG. 4 is a graph illustrating the concentration of dopants as a function of the depth of an impurity implantation region taken alone a line I-I′ of FIG. 2;

FIG. 5 is a graph illustrating the concentration of dopants as a function of the depth of an impurity doped region taken along a line II-II′ of FIG. 3;

FIG. 6 is a flowchart illustrating a method of forming an impurity doped region according to an exemplary embodiment of the present invention;

FIGS. 7 and 8 are sectional views illustrating a method of forming a semiconductor device according to an exemplary embodiment of the present invention;

FIG. 9 is a perspective view of a semiconductor device including an impurity doped region according to an exemplary embodiment of the present invention; and

FIG. 10 is a graph illustrating the concentration of dopants as a function of the depth of an impurity doped region taken along a line III-III′ of FIG. 9.

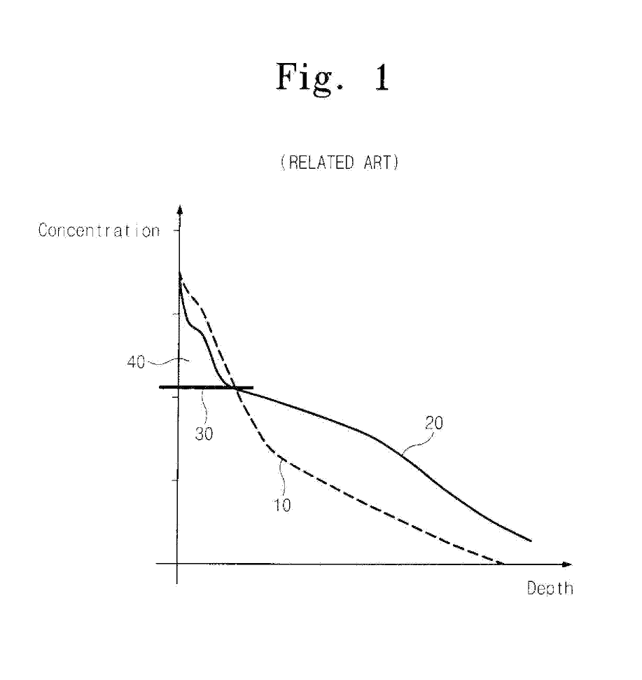

### DETAILED DESCRIPTION OF THE EXEMPLARY EMBODIMENTS

Exemplary embodiments of the present invention will be described below in more detail with reference to the accompanying drawings. The present invention may, however, be embodiment in different forms and should not be constructed as limited to the exemplary embodiments set forth herein. In the figures, the dimensions of layers and regions may be exaggerated for clarity of illustration. Like reference numerals may refer to like elements throughout.

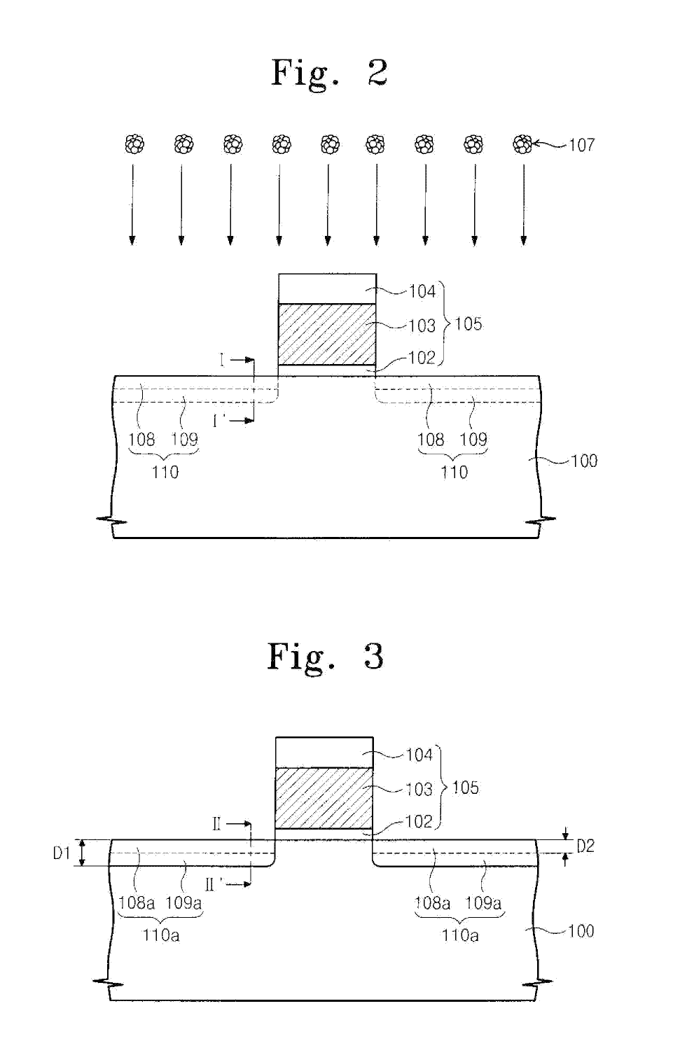

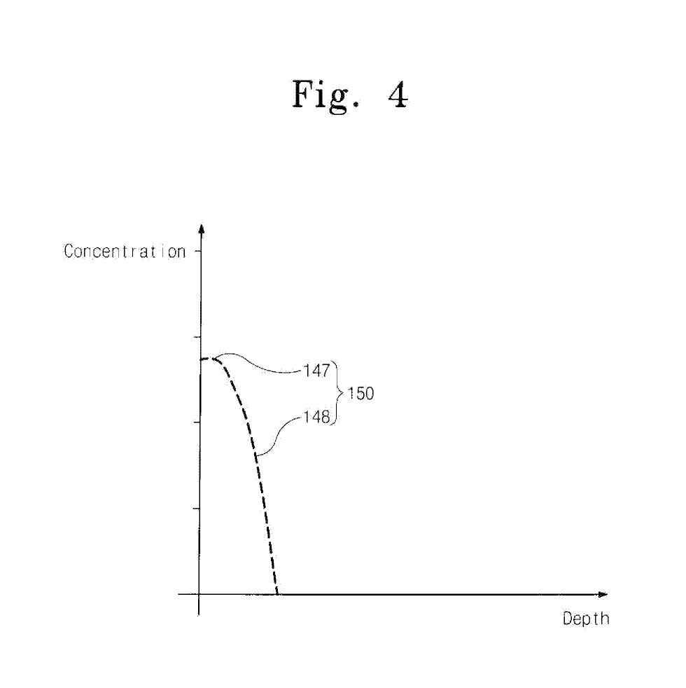

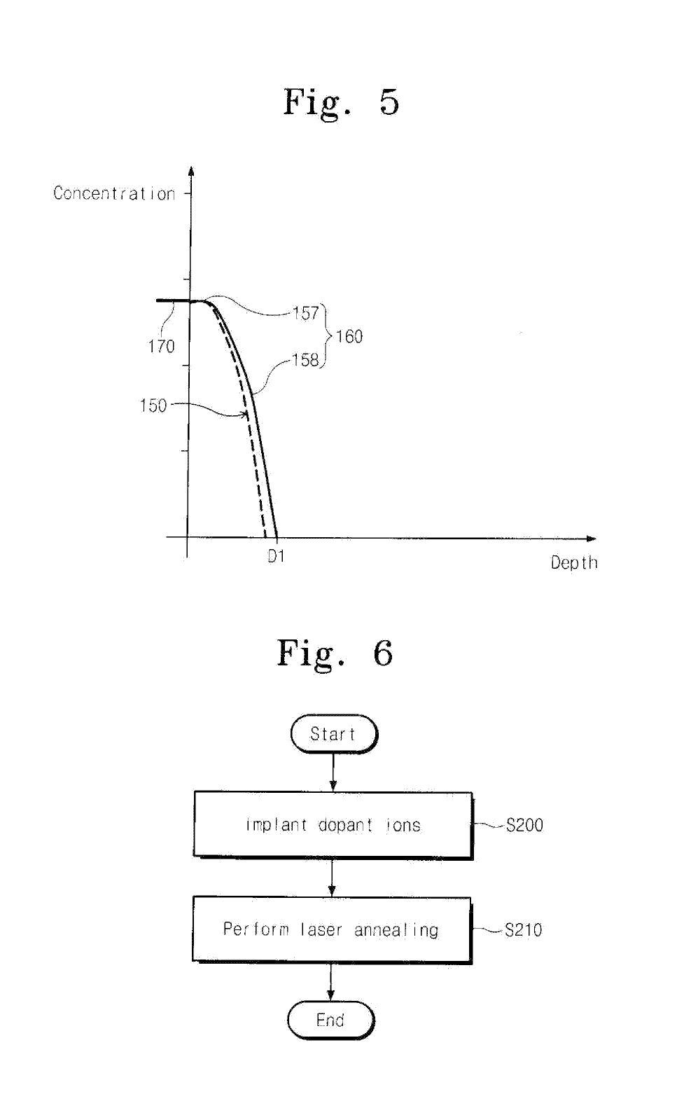

FIGS. 2 and 3 are sectional views illustrating a method of forming a semiconductor device including an impurity doped region according to an exemplary embodiment of the present invention. FIG. illustrates the dopant concentration as a result of the depth of the impurity doped region taken along a line I-I′ of FIG. 2. FIG. 5 illustrates the dopant concentration as a result of the depth of the impurity doped region taken along a line II-II′ of FIG. 3. FIG. 6 is a flowchart illustrating a method of forming an impurity doped region according to an exemplary embodiment of the present invention.

Referring to FIG. 2, a gate pattern 105 is formed on a semiconductor substrate 100. The gate pattern 105 includes a gate insulating layer 102 and a gate electrode 103 that are sequentially stacked on the semiconductor substrate 100. The gate pattern 105 may further include a capping insulating pattern 104 disposed on the gate electrode 103. The gate insulating layer 102 may be formed of a silicon oxide layer, for example, a thermal oxide layer. The gate electrode 103 is formed of a conductive material. For example, the gate electrode 103 may be formed of at least one selected from the group consisting of doped polysilicon, a metal such as tungsten and molybdenum, a conductive metal nitride such as titanium nitride and tantalum nitride, and a metal silicide such as tungsten silicide and cobalt silicide. The capping insulating pattern 104 may be formed of silicon nitride, silicon oxide, or silicon oxynitride. A device isolation layer (not shown) may be formed in the semiconductor substrate 100 to define an active region, prior to forming of the gate pattern 105. The gate pattern 105 crosses over the active region.

A method of forming an impurity doped region is described below. The method is described with reference to the flowchart of FIG. 6 and graphs representing the concentration profiles of dopants in FIGS. 4 and 5.

Referring to FIGS. 2, 4 and 6, dopant ions 107 are implanted into the semiconductor substrate 100 using the gate pattern 105 as a mask (S200) to form impurity implantation regions 110 at both sides of the gate pattern 105 in the semiconductor substrate 100. The dopant ions 107 may have a cluster-shape where a plurality, of dopant units, including dopant atoms or dopant molecules, are bound with one another. The cluster-shaped dopant ions 107 may each contain about one thousand to fifty thousand dopant atoms. The dopant atoms or the dopant molecules constituting the cluster-shaped dopant ion 107 may be loosely bound.

A method of forming the cluster-shaped dopant ion 107 according to an exemplary embodiment of the present invention is described below. A plurality of dopant atoms or molecules are implanted at a high speed into a chamber having a low pressure. Then, a temperature in the chamber decreases due to adiabatic expansion. The plurality of dopant atoms or molecules in the chamber are solidified and thus form a particle due to a low temperature. Here, the solidified particle is formed in a cluster-shape containing a plurality of dopant atoms or molecules that are loosely bound with one another. Subsequently, the particle is ioinized. The ionized particle corresponds to the cluster-shaped dopant ion 107.

In the ion implantation process, the cluster-shaped dopant ion 107 collides with a surface of the semiconductor substrate 100 and resolves. The resolved elements are implanted into the semiconductor substrate 100. The dopants implanted into the impurity implantation region 110 have an implant concentration profile 150 illustrated in FIG. 4. In FIG. 4, a horizontal axis represents a depth from an upper surface of the semiconductor substrate 100, and a vertical axis represents a concentration of dopant.

After the dopant ion 107 collision, the dopant concentration of an upper portion 108 of the impurity implantation region 110 has a first implantation profile 147 and a lower portion 109 of the impurity implantation region 110 has a second implantation profile 148. The upper portion 108 of the impurity implantation region 110 is defined as an upper implantation region and the lower portion 109 of the impurity implantation region 1100 is defined as a lower implantation region. As illustrated in FIG. 4, the dopant concentration of the upper implantation portion 108 varies gently as a function of depth. For example, the dopant concentration of the upper implantation portion 108 is relatively uniform. Dispersion of the dopant concentration of the upper implantation portion 108 may be less than 20%. The upper implantation portion 108 includes a maximum implantation portion where the dopant concentration reaches its maximum. The dopant concentration of the lower implantation portion 109 sharply decreases as depth increases.

As described above, the upper implantation portion 108 has a relatively uniform concentration because of the cluster-shaped dopant ions 107. Accordingly, an amount of dopants implanted into an upper surface of the impurity implantation region 110, for example a surface of the semiconductor substrate 100, is sharply decreased compared to the conventional case. Because a region having a relatively uniform concentration is formed in the upper implantation portion 108, the impurity doped region may exhibit an excellent electrical property and can be formed by implanting a relatively small amount of dopant into a surface of the semiconductor substrate. In addition, since the size of the cluster-shaped dopant ions 107 are much larger than an atomic lattice of the semiconductor substrate 100, channeling does not occur. As a result, the implant concentration profile 150 of the impurity implantation region 110 is formed nearly in an ideal box-shape, compared to the conventional implant concentration profile.

Referring to FIGS. 3, 5, and 6, a laser annealing process is performed on the impurity implantation region 110 (S210). Dopants in the impurity implantation region 110 are activated to form an impurity doped region 110a having desired electrical properties as a result of the laser annealing process. A doping concentration profile 160 represents a dopant concentration of the impurity doped region 110a. In FIG. 5, a horizontal axis represents a depth from an upper surface of the semiconductor substrate 100 and a vertical axis represents a concentration of dopant.

In the laser annealing process, the impurity implantation region 110 is irradiated by a laser beam. The laser annealing process may be performed for a comparatively short annealing time by controlling the laser beam irradiating time, compared to the conventional RTA process. The annealing time of the laser annealing process (hereinafter also referred to as a laser annealing time) may range from about 1 microsecond to 1 second. The laser annealing process may provide a relatively high temperature compared to the conventional RTA process.

Since the annealing time of the laser annealing process is comparatively short, compared to the annealing time of the conventional RTA process, the diffusion of dopants due to the laser annealing process can be minimized. Also, since the laser annealing process may provide a high temperature and may have a comparatively short laser annealing time, compared to the RTA process, the annealing temperature thereof may be freely increased, compared to the conventional RTA process. As a result, the laser annealing process can minimize the diffusion of dopants and provide a high temperature annealing process to the impurity implantation region 110. The annealing temperature of the laser annealing process (the laser temperature) may be within the range of about 1000-1450° C.

An upper doped portion 108a of the impurity doped region 110a has a dopant concentration profile resulting from the upper implantation portion 108. A lower doped portion 109a of the impurity doped region 110a has a dopant concentration profile resulting from the lower implantation portion 109. For example the upper doped portion 108a has a first doping profile 157 of the doping concentration profile 160. The upper doped portion 108a has a concentration dispersion less than 20%, and the distribution of the dopants is relatively uniform. The dopant concentration of the lower doped portion 109a sharply decreases as depth increases. The lower doped portion 109a has a second doping profile 158 of the doping concentration profile 160. A lower surface of the upper doped portion 108a may be formed slightly deeper than a lower surface of the upper implantation portion 108. A lower surface of the lower doped portion 109a may be formed slightly deeper than a lower surface of the lower implantation portion 109.

A solubility limit concentration 170 of the impurity implantation region 110 may be increased by increasing the laser annealing temperature. The solubility limit concentration 170 is a maximum amount of dopants that can be activated at the laser annealing temperature. The solubility limit concentration 170 changes depending on the laser annealing temperature. As the laser annealing temperature increases the solubility limit temperature 170 increases.

An amount of dopant activated in the upper doped portion 108a may be substantially increased by increasing the solubility limit concentration 170 using the laser annealing temperature. Therefore, a resistance of the impurity doped region 110a may be substantially decreased. As an amount of dopant activated in the upper doped portion 108a is substantially increased, an amount of inactivated dopant in the upper doped portion 108a may be substantially decreased. For example all dopant in the upper doped portion 108a may be activated.

The dopant concentration of a maximum implantation portion of the impurity implantation region 110 (the maximum dopant concentration of the impurity implantation region 110) is smaller than 4 times the solubility limit concentration 170 according to the laser annealing temperature. Therefore, there may be less than three times as much inactivated dopant as activated dopant in the upper doped portion 108a. When there is less than three times as much inactivated dopant as activated dopant, defects such as vacancy and/or dislocation are minimized, for example, to an amount that almost does not affect the electrical property of the impurity doped region 110a.

For example, the maximum dopant concentration of the impurity implantation region 110 may be equal to or higher than the solubility limit concentration 170 and may be smaller than 4 times the solubility limit concentration 170. The maximum dopant concentration of the impurity implantation region 110 may be equal to the solubility limit concentration 170. In this case, all dopants may be activated in the impurity doped region 110a. Accordingly, defects such as vacancy or/and dislocation may be prevented.

When the laser annealing temperature is 1450° C. and the dopant is arsenic having low activation energy, the solubility limit concentration 170 is approximately 5×10²¹/cm³. When the laser annealing temperature is 1000° C. and the dopant is boron having high activation energy, the solubility limit concentration 170 is approximately 5×10¹⁹/cm³. Therefore, the maximum dopant concentration of the impurity implantation region 110 may range from about 5×10¹⁹/cm³ to about 2×10²²/cm³. In particular, since boron has a degree of activation lower than that of arsenic and phosphorus, when the laser annealing temperature is 1450° C. the solubility limit concentration 170 of boron is approximately 6×10²⁰/cm³. Therefore, when the dopant is boron, the maximum dopant concentration of the impurity implantation region 110 may range from about 5×10¹⁹/cm³ to about 2.4×10²¹/cm³.

A dose of the cluster-shaped impurity ions 107 suitable for realizing the maximum dopant concentration of the impurity implantation region 110 may change depending on implantation energy and the kind of dopant used. For example the cluster-shaped dopant ions having a dose of 2.5×10¹⁴/cm³ and 5 KeV of energy may be implanted to achieve boron having the concentration of 6×10²⁰/cm³.

A lower surface of the impurity doped region 110a is formed at a first depth D1 from an upper surface of the semiconductor substrate 100 and a lower surface of the upper doped portion 108a is formed at a second depth D2 from the upper surface of the semiconductor substrate 100. The second depth D2 may be ¼ of the first depth D1 and may be smaller than the first depth D1. A depth of a lower surface of the lower doped portion 109a is equal to the first depth D1. For example, the lower surface of the lower doped portion 109a becomes the lower surface of the impurity doped region 110a.

The impurity doped region 110a may be formed so as to have a very small depth and excellent electrical properties by performing the ion implantation process (S200) using the cluster-shaped dopant ions 107 and the laser annealing process (S210). The lower surface of the impurity doped region 110a may be formed at a depth of about 1-15 nm.

The impurity doped region 110a may be used as source/drain regions of a single layer included in a dynamic random access memory (DRAM) cell or a NAND flash memory cell.

The impurity doped region 110a may be used as a lightly doped region of an LDD structure, source/drain regions and/or an extended portion of extended source/drain regions. A method of forming the impurity doped region 110a will be described with reference to the accompanying drawings.

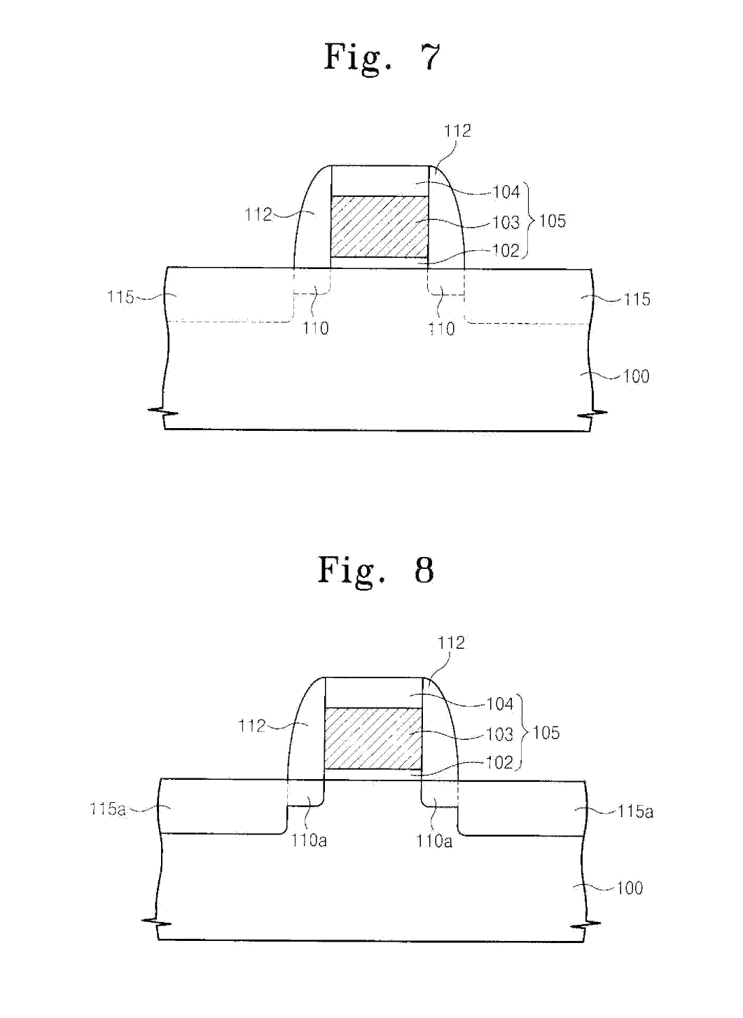

FIGS. 7 and 8 are sectional views illustrating a method of forming a semiconductor device according to an exemplary embodiment of the present invention.

Referring to FIGS. 2 and 7, after forming the impurity implantation region 110, spacers 112 are formed on both sidewalls of the gate pattern 105. The spacers 112 may be formed of at least one of silicon nitride, silicon oxide, and silicon oxynitride.

High dose of dopant ions are implanted using the gate pattern 105 and the spacers 112 to form a heavily doped implantation region 115. Dopants of the heavily doped implantation region 115 may be of the same type as dopants of the impurity implantation region 110. Dopant ions for forming the heavily doped implantation region 115 may be monoatomic dopant ions, monomolecular dopant ions or cluster-shaped dopant ions. A dopant concentration of the impurity implantation region 110 may be lower than a dopant concentration of the heavily doped implantation region 115. In this case, the source/drain regions may be formed in the LDD structure. Alternatively, the dopant concentration of the impurity implantation region 110 may be about equal to the dopant concentration of the heavily doped implantation region 115. In this case, the source/drain region may be formed in the extended type structure. The dopant ions for forming the heavily doped implantation region 115 may be implanted with energy higher than the dopant ions, for forming the impurity implantation region 110.

Referring to FIG. 8, the laser annealing process which is described with reference to FIGS. 3 and 5, and S200 of FIG. 6, is performed on the semiconductor substrate 100. The semiconductor substrate 100 includes the impurity implantation region 110 and the heavily doped implantation region 115 and an impurity doped region 110a and a heavily doped region 115a are formed thereon. The impurity and heavily doped regions 110a and 115a constitute source/drain regions.

Next, a semiconductor device according to the exemplary embodiment of the present invention will be described with reference to the accompanying drawings.

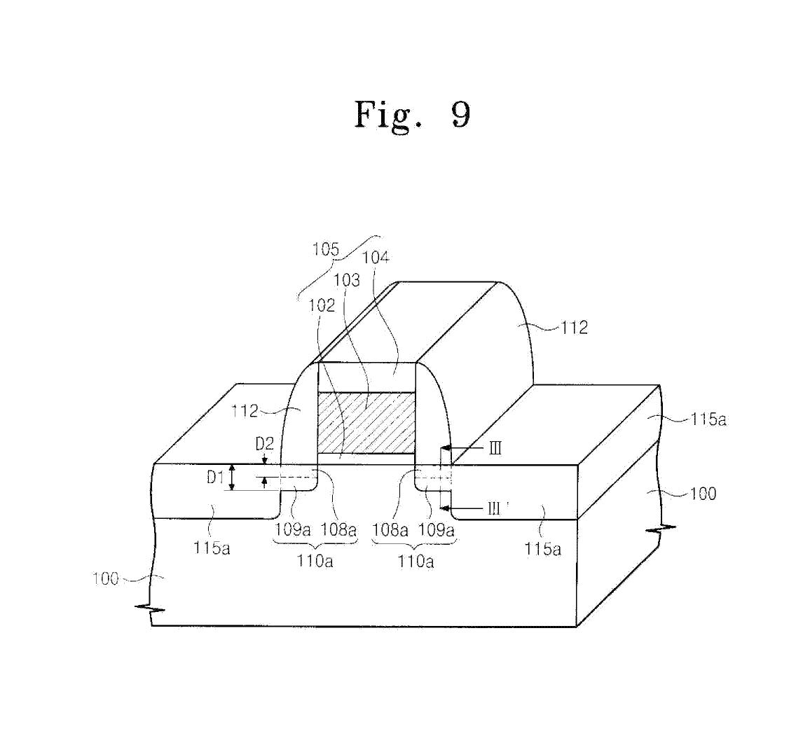

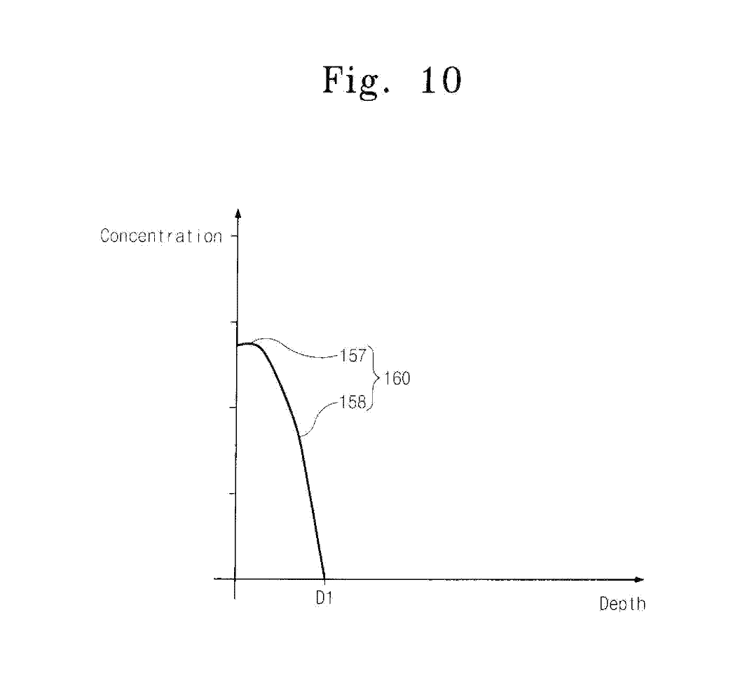

FIG. 9 is a perspective view of a semiconductor device including an impurity doped region according to an exemplary embodiment of the present invention. FIG. 10 illustrates a dopant concentration as a function of the depth of the impurity doped region taken along a line III-III′ of FIG. 9.

Referring to FIG. 9 and 10, a gate pattern 105 is formed on a semiconductor substrate 100. The gate pattern 105 includes a gate electrode 103. The gate pattern 105 further includes a gate insulating layer 102 interposed between the gate electrode 103 and the semiconductor substrate 100. The gate pattern 105 may further include a capping insulating pattern 104 formed on the gate electrode 103.

Source/drain regions are formed at both sides of the gate pattern 105 in the semiconductor substrate 100, respectively. The source/drain regions include impurity doped regions 110a. An upper portion of the impurity doped region 110a is defined as an upper doped portion 108a and a lower portion of the impurity doped region 110a is defined as a lower doped portion 109a.

A doping concentration profile 160 of the impurity doped region 110a is illustrated in 10. The doping concentration profile 160 includes a first doping profile 157 and a second doping profile 158. The dopant concentration of the upper doped portion 108a has the first doping profile 157 and the dopant concentration of the lower doped portion 109a has the second doping profile 158. In more detail, the upper doped portion 108a has a concentration dispersion of less than 20% so that the distribution of the dopant is relatively uniform. The dopant concentration of the lower doped portion 109a sharply decreases as depth increases.

A lower surface of the impurity doped region 110a is located at a first depth D1 from a surface of the semiconductor substrate 100. The first depth D1 becomes a junction depth of the impurity doped region 110a. A lower surface of the upper doped portion 108a is located at a second depth D2 from the surface of the semiconductor substrate 100. The second depth D2 may be at least ¼ of the first depth D1 and may be smaller than the first depth D1. An upper surface of the impurity doped region 110a may be the same as an upper surface of the upper doped portion 108a and the surface of the semiconductor substrate 100. A lower surface of the lower doped portion 109a is located at the first depth D1. For example, the lower surface of the lower doped portion 109a may be the same as a lower surface of the impurity doped region 110a.

Spacers 112 are formed on sidewalls of the gate pattern 105. The impurity doped region 110a may be disposed under the spacers 112. A heavily doped region 115a may be formed at a side of the impurity doped region 110a. For example, the impurity doped region 110a is disposed between a channel region under the gate pattern 105 and the heavily doped region 115a. The impurity doped region 110a is electrically connected with the heavily doped region 115a to constitute the source/drain regions. The impurity doped region 110a may have a dopant concentration lower than a dopant concentration of the heavily doped region 115a. In this example, the source/drain regions have an LDD structure. Alternatively, the impurity doped region 110a may have a dopant concentration about equal to a dopant concentration of the heavily doped region 115a. In this example, the source/drain regions have an extended structure.

Alternatively, the source/drain regions may include only the impurity doped region 110a. In this case, the heavily doped region 115a is omitted and one end of the impurity doped region 110a laterally extends along the surface of the semiconductor substrate 100 relatively far from the gate pattern 105.

In the upper doped portion 108a, the quantity of inactivated dopant is less than 3 times the quantity of activated dopant. The upper doped portion 108a may include only the activated dopants. When all dopants are activated in the upper doped portion 108a, all dopants are activated in the lower doped portion 109a, and consequently, all dopants are activated in the impurity doped region 110a.

The upper doped portion 108a is formed by performing the laser annealing process on the upper implantation portion 108 illustrated with reference to FIG. 2. As described above, the maximum dopant concentration of the upper implantation portion 108 may range from about 5×10¹⁹/cm³ to about 2×10²/cm³. Dopants in the upper implantation portion 108 illustrated in FIG. 2 are slightly diffused through the laser annealing process. Therefore the maximum value of the maximum dopant concentration of the upper doped portion 108a may be smaller than about 2×10²²/cm³. The minimum value of the maximum dopant concentration of the upper doped portion 108a may be smaller than about 5×10¹⁹/cm³. However, the minimum value of the maximum dopant concentration of the upper doped portion 108a is larger than about 4×10¹⁹/cm³. As a result, the maximum concentration of the upper doped portion 108a may be higher than about 4×10¹⁹/cm³ and lower than about 2×10²²/cm³. Similarly, when the dopant is boron, the maximum dopant concentration of the upper doped portion 108a may be higher than about 4×10¹⁹/cm³ and lower than about 2.4×10²¹/cm³.

A lower surface of the impurity doped region 110a may be formed at a depth where the dopant concentration of the impurity doped region 110a is about 1×10¹⁸/cm³.

The first depth D1 of the impurity doped region 110a may be within the range of about 1-15 nm.

As described above, according to an exemplary embodiment of the present invention, cluster-shaped dopant ions are implanted to form an impurity implantation region having a concentration profile resembling an ideal box-shape. Next, a laser annealing process is performed on the impurity implantation region for an annealing time of about 1 second or shorter to form an impurity doped region. Therefore, an amount of inactivated dopant can be greatly reduced in a surface of a semiconductor substrate. As a result, conventional defects can be minimized to minimize the degradation of an electrical property of the impurity doped region.

In addition, the laser annealing process can provide a relatively short annealing time and a high annealing temperature. Therefore, the solubility, limit concentration can be increased to increase an amount of activated dopant in the impurity doped region. Consequently, an impurity doped region having a very low resistance can be formed.

As a result, the impurity doped region having a very small depth and an excellent electrical property can be formed to realize a semiconductor device optimized for high integration.

The above exemplary embodiments are illustrative, and many variations can be introduced on these exemplary embodiments without departing from the spirit of the disclosure or from the scope of the appended claims. For example, elements and/or features of different exemplary embodiments may be combined with each other and/or substituted for each other within the scope of this disclosure and appended claims.

What is claimed is:

1. A method of forming a semiconductor device, the method comprising:
implanting one or more cluster-shaped dopant ions into a semiconductor substrate to form an impurity implantation region; and
performing a laser annealing process on the impurity, implantation to form an impurity doped region,
wherein the cluster-shaped dopant ions comprise a plurality of dopant units that are bound with one another.

2. The method of claim 1, wherein the dopant units are atoms of dopant.

3. The method of claim 1, wherein the dopant units are molecules of dopant.

4. The method of claim 1, wherein an upper portion of the impurity implantation region includes a maximum implantation portion having a dopant concentration that is greater than a dopant concentration of the remainder of the impurity implantation region, and
the dopant concentration of the maximum implantation portion is less than or equal to about 4 times a solubility, limit concentration according to an annealing temperature of the laser annealing process.

5. The method of claim 4, wherein the dopant concentration of the maximum implantation portion is equal to or greater than the solubility limit concentration.

6. The method of claim 4, wherein the dopant concentration of the maximum implantation portion is within the range of about 5×10¹⁹/cm³ to about 2×10²²/cm³.

7. The method of claim 6, wherein the dopant is boron and the dopant concentration of the maximum implantation portion is within the range of about 5×10¹⁹/cm³ to about 2.4×10²¹/cm³.

8. The method of claim 1, wherein an annealing temperature of the laser annealing process is in the range of about 1000° C. to about 1450° C.

9. The method of claim 1, wherein the laser annealing process is performed by the impurity implantation region with a laser beam and the annealing time of the laser annealing process ranges from about 1 microsecond to about 1 second.

10. The method of claim 1, wherein an upper doped portion, comprising an upper portion of the impurity doped region, has a dopant concentration dispersion of less than about 20%.

11. The method of claim 1, wherein a lower surface of the impurity doped region is formed at a first depth from an upper surface of the semiconductor substrate, a lower surface of the upper doped portion is formed at a second depth from the upper surface of the semiconductor substrate, and
the second depth is equal to or larger than about ¼ of the first depth and is smaller than about the first depth.

12. The method of claim 10, wherein a lower surface of a lower doped portion comprises a lower portion of the impurity doped region and the lower surface of the lower doped portion is formed at the first depth and a dopant concentration of the lower doped portion substantially decreases as depth increases.

13. The method of claim 1, wherein a depth of a lower surface of the impurity doped region is within the range of about 1 nm to about 15 nm.

14. The method of claim 1, further comprising forming a gate electrode disposed on the semiconductor substrate with a gate insulating layer interposed therebetween before the forming of the impurity implantation region,
wherein the cluster-shaped dopant ions are implanted using the gate electrode as a mask and the impurity implantation region is formed at two sides of the gate electrode in the semiconductor substrate.

15. A semiconductor device, comprising:
a semiconductor substrate; and
an impurity doped region formed in the semiconductor substrate,
wherein an upper doped portion, comprising an upper portion of the impurity doped region, has a dopant concentration dispersion of less than about 20% and a dopant concentration of a lower doped portion, comprising a lower portion of the impurity doped region, substantially decreases as depth increases.

16. The semiconductor device of claim 15, wherein a lower surface of the impurity doped region is located at a first depth from an upper surface of the semiconductor substrate and a lower surface of the upper doped portion is formed at a second depth from the upper surface of the semiconductor substrate,
the second depth being equal to or greater than about ¼ of the first depth and smaller than about the first depth, and a lower surface of the lower doped portion is located at the first depth.

17. The semiconductor device of claim 15, wherein there are less than 3 times as much inactivated dopant as activated dopant in the upper doped portion.

18. The semiconductor device of claim 15, wherein activated dopants exist in the upper doped portion and inactivated dopants are absent from the upper doped portion.

19. The semiconductor device of claim 15, wherein a maximum dopant concentration of the upper doped portion is higher than about 4×10¹⁹/cm³ and lower than about 2×10²²/cm³.

20. The semiconductor device of claim 19, wherein the dopant is boron and the maximum dopant concentration of the upper doped portion is higher than about 4×10¹⁹/cm³ and lower than about 2.4×10²¹/cm³.

21. The semiconductor device of claim 15, wherein a depth of the impurity doped region is within the range of about 1 nm to about 15 nm.

22. The semiconductor device of claim 15, further comprising:
a gate electrode disposed at a side of the impurity doped region on the semiconductor substrate; and
a gate insulating layer interposed between the gate electrode and the semiconductor substrate.
